(19) United States
(12) Patent Application Publication
(10) Pub. No.: US 2008/0265254 A1
(43) Pub. Date: Oct. 30, 2008

(54) THIN FILM TRANSISTOR ARRAY SUBSTRATE, METHOD OF MANUFACTURING SAME, AND DISPLAY DEVICE

(75) Inventor: Atsunori NISHIURA, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: MITSUBISHI ELECTRIC CORPORATION, Chiyoda-ku (JP)

(21) Appl. No.: 12/107,431

(22) Filed: Apr. 22, 2008

(30) Foreign Application Priority Data
Apr. 27, 2007 (JP) 2007-120168

(51) Int. Cl. H01L 31/0224; H01L 31/18

(52) U.S. Cl. 257/59; 438/29; 257/E31.001; 257/E21.002

(57) ABSTRACT

A thin film transistor array substrate in accordance with the present invention comprising a semiconductor layer formed over the substrate and having source/drain regions, a gate insulating film, a gate electrode, an interlayer insulating film, wiring electrodes connected to the source/drain regions, a protective film, a pixel electrode connected to the wiring electrode, a lower capacitor electrode formed with and extending from the semiconductor layer, a common line electrode formed from the same layer as the gate electrode and arranged in the opposed position to the lower capacitor electrode with the gate insulating film interposed therebetween, and an upper capacitor electrode arranged in the opposed position to the common line electrode with a dielectric film (protective film) having film thickness thinner than the interlayer insulating film interposed therebetween.

### BACKGROUND OF THE INVENTION

1. Field of the Invention

The present invention relates to a thin film transistor array substrate, a method of manufacturing the same, and a display device. In particular, the present invention relates to a thin film transistor array substrate having storage capacitor elements, a method of manufacturing the same, and a display device.

2. Description of Related Art

In recent years, the development of a flat panel display device using TFTs (Thin Film Transistors), such as a liquid crystal display device and an EL (Electro Luminescence) display device has been promoted. Particularly, a TFT using polysilicon as material for a semiconductor layer active region (which is called “polysilicon TFT” hereinafter) allows the formation of a higher definition panel compared to a conventional TFT using amorphous silicon. A polysilicon TFT also allows the integral formation of a driving circuit region and a pixel region. Furthermore, a polysilicon TFT can reduces the manufacturing cost since it does not need a driving circuit chip and the mounting cost thereof. As just described, a polysilicon TFT has a variety of advantages, and has been attracting increasing attention.

The structures of a TFT are mainly categorized into a bottom-gate type and a top-gate type. In the bottom-gate type, a gate electrode is located below source and drain electrodes with a semiconductor layer interposed therebetween. On the other hand, in the top-gate type, a gate electrode is located above source and drain electrodes with a semiconductor layer interposed therebetween. For a polysilicon TFT, the top-gate type has become mainstream type since it allows high-temperature silicon crystallization process to be performed before any other processes.

A method of manufacturing a conventional top-gate type TFT array substrate is explained hereinafter with reference to FIGS. 7A and 7B. FIG. 7A is a plan view of the structure of a storage capacitor element in accordance with a first related art. Pixel structure of a top-gate type TFT array substrate of the first related art is shown in FIG. 7A. FIG. 7B is a cross-section view showing the structure of the storage capacitor element in accordance with the first related art. Schematic cross-sectional structure of the TFT and storage capacitor element of FIG. 7A is shown in FIG. 7B.

Firstly, an undercoat insulating film 2 is formed on a substrate 1 composed of a transparent insulating substrate such as glass. Then, a polysilicon film is formed on the undercoat insulating film 2. The polysilicon film is patterned through photolithography, etching, and resist-removal processes to form a semiconductor layer 3. At this point, as shown in FIGS. 7A and 7B, the lower capacitor electrode 3a of a storage capacitor element 20 is formed simultaneously with the semiconductor layer 3 through the polysilicon film patterning process.

Next, using a silicon dioxide film or the like, the thin film of a gate insulating film 4 is deposited such that the gate insulating film 4 covers the semiconductor layer 3 and the lower capacitor electrode 3a. Furthermore, a first metal film is formed on the gate insulating film 4, and then patterned to form a gate electrode 5 above the channel region of the semiconductor layer 3. At this point, as shown in FIGS. 7A and 7B, a common line electrode 5a is formed above the lower capacitor electrode 3a simultaneously with the gate electrode 5 through the first metal film patterning process. Then, an impurity is introduced in the source/drain regions of the semiconductor layer 3 using the gate electrode 5 as a mask.

After the introduction of the impurity, an interlayer insulating film 6 is formed such that the interlayer insulating film 6 covers the gate electrode 5 and common line electrode 5a. Then, the interlayer insulating film 6 and gate insulating film 4 are removed by etching to form contact-holes 10 on the source/drain regions of the semiconductor layer 3. Wiring electrodes 71 and 72 which are electrically connected to the semiconductor layer 3 thorough the contact-holes 10 are formed with a second metal film.

A protective film 8 is formed to cover the wiring electrodes 71 and 72, and then patterned to form a through-hole 11 on the wiring electrode 72. A pixel electrode 9 which connects to the wiring electrode 72 through the through-hole 11 is formed on the protective film 8 on a pixel-by-pixel basis. In this manner, a conventional top-gate type TFT array substrate is manufactured.

As described above, in a conventional top-gate type TFT array substrate, the storage capacitor element 20 is constructed with the lower capacitor electrode 3a and common line electrode 5a, which are arranged in opposed positions with the gate insulating film 4 interposed therebetween, using the gate insulating film 4 as a dielectric film (first related art). Since both of the lower capacitor electrode 3a and the semiconductor layer 3 are formed by a single process and both of the common line electrode 5a and the gate electrode 5 are formed by a single process, the number of processes can be reduced and thus the productivity is improved.

In general, the storage capacitance of a storage capacitor element is determined by the dielectric constant and film thickness of a dielectric film, and the area of electrodes arranged in opposed positions with the dielectric film interposed therebetween. Particularly, the extension of the electrode areas to increase the storage capacitance has a certain limitation in terms of circuit design and process design, because it leads to the increase of the circuit area, the decrease of light amount transmitted from a backlight owing to the decreased transparent area, the need for the miniaturization of TFT, and the like.

To solve such problem, there is a known method for securing a certain amount of the storage capacitance in which a set of opposed electrodes are arranged each above and below the common line electrode 5 used for voltage clamp such that two storage capacitor elements are formed, and both storage capacitor elements are connected in parallel (second related art). The second related art is explained hereinafter with reference to FIGS. 8A and 8B. FIG. 8A is a plan view showing the structure of a storage capacitor element in accordance with the second related art. Pixel structure of a top-gate type TFT array substrate of the second related art is shown in FIG. 8A. FIG. 8B is a cross-section view showing the structure of the storage capacitor element in accordance with the second related art. Schematic cross-sectional structure of the TFT and storage capacitor element of FIG. 8A is shown in FIG. 8B.

In FIGS. 8A and 8B, similarly to the first related art shown in FIGS. 7A and 7B, a common line electrode 5a and a lower capacitor electrode 3a, which is located under the common line electrode 5a and in the same layer as a semiconductor layer 3, form opposed electrodes with a gate insulating film 4 interposed therebetween, and constitute a storage capacitor element 20. Furthermore, the common line electrode 5a and an upper capacitor electrode 7a, which is located above the common line electrode 5a and in the same layer as a wiring electrode 7, form opposed electrodes with an interlayer insulating film 6 interposed therebetween, and constitute a storage capacitor element 25. The semiconductor layer 3 and wiring electrode 7 are electrically connected each other through a contact-hole 10 which pierces the interlayer insulating film 6 and the gate insulating film 4 (for example, see Japanese unexamined patent publication Nos. 2003-98515, 2000-298290, and 9-43640).

FIGS. 9A and 9B show the equivalent circuits of these related art pixel structures. FIG. 9A shows the pixel equivalent circuit according to the first related art and FIG. 9B shows the pixel equivalent circuit according to the second related art. While a single storage capacitor element is provided in the first related art as shown in FIG. 9A, two storage capacitor elements are provided in the second related art as shown in FIG. 9B. That is, the second related art has additional storage capacitance corresponding to one storage capacitor element compared to the first related art. Therefore, since storage capacitance per unit area is larger in the second related art, it can reduce the area of the storage capacitor elements.

However, the thickness of the interlayer insulating film 6 which is used as a dielectric film is four to six times as thick as the gate insulating film 4. That is, in the second related art, the storage capacitance of the storage capacitor element 25 composed of the common line electrode 5a, the interlayer insulating film 6, and the upper capacitor electrode 7a is merely one sixth to one fourth of the storage capacitor element 20 composed of the common line electrode 5a, the gate insulating film 4, and the lower capacitor electrode 3a. Therefore, there is a problem that the area of the storage capacitor element can only be reduced slightly since the increase of the storage capacitance per unit area is small.

The present invention has been made to solve these problems, and the object of the invention is to provide a thin film transistor array substrate capable of reducing the area occupied by storage capacitor elements, a method of manufacturing the same, and a display device.

### SUMMARY OF THE INVENTION

In accordance with one aspect of the present invention, a thin film transistor array substrate comprises: a semiconductor layer formed over the substrate and having source/drain regions; a gate insulating film covering the semiconductor layer; a gate electrode arranged in the opposed position to the channel region of the semiconductor layer with the gate insulating film interposed therebetween; an interlayer insulating film covering the gate electrode; a wiring electrode connected to the source/drain regions through a contact hole piercing through the interlayer insulating film and the gate insulating film; a protective film covering the wiring electrode and the interlayer insulating film; a pixel electrode connected to the wiring electrode through a through hole piercing through the protective film; a lower capacitor electrode formed with and extending from the semiconductor layer; a common line electrode formed from the same layer as the gate electrode and arranged in the opposed position to the lower capacitor electrode with the gate insulating film interposed therebetween; and an upper capacitor electrode arranged in the opposed position to the common line electrode with a dielectric film having film thickness thinner than the interlayer insulating film interposed therebetween.

In accordance with one aspect, the present invention provides a thin film transistor array substrate capable of reducing the area occupied by storage capacitor elements, a method of manufacturing the same, and a display device.

The above and other objects, features and advantages of the present invention will become more fully understood from the detailed description given hereinbelow and the accompanying drawings which are given by way of illustration only, and thus are not to be considered as limiting the present invention.

### BRIEF DESCRIPTION OF THE DRAWINGS

FIG. 1 is a front view showing the structure of a TFT array substrate in accordance with a first embodiment of the present invention;

FIG. 2A is a plan view showing the structure of a storage capacitor element in accordance with the first embodiment of the present invention;

FIG. 2B is a cross-section view showing the structure of the storage capacitor element in accordance with the first embodiment of the present invention;

FIG. 3A is a plan view showing the structure of a storage capacitor element in accordance with a second embodiment of the present invention;

FIG. 3B is a cross-section view showing the structure of the storage capacitor element in accordance with the second embodiment of the present invention;

FIGS. 4A to 4D are cross-section views showing an example of the manufacturing process of a TFT array substrate in accordance with the second embodiment of the present invention;

FIGS. 5A to 5D are cross-section views showing another example of the manufacturing process of the TFT array substrate in accordance with the second embodiment of the present invention;

FIG. 6A is a plan view showing the structure of a storage capacitor element in accordance with a third embodiment of the present invention;

FIG. 6B is a cross-section view showing the structure of the storage capacitor element in accordance with the third embodiment of the present invention;

FIG. 7A is a plan view showing the structure of a storage capacitor element in accordance with a first related art;

FIG. 7B is a cross-section view showing the structure of the storage capacitor element in accordance with the first related art;

FIG. 8A is a plan view showing the structure of a storage capacitor element in accordance with a second related art;

FIG. 8B is a cross-section view showing the structure of the storage capacitor element in accordance with the second related art;

FIG. 9A shows a pixel equivalent circuit of the first related art; and

FIG. 9B shows a pixel equivalent circuit of the second related art.

### DESCRIPTION OF THE PREFERRED EMBODIMENTS

### First Embodiment

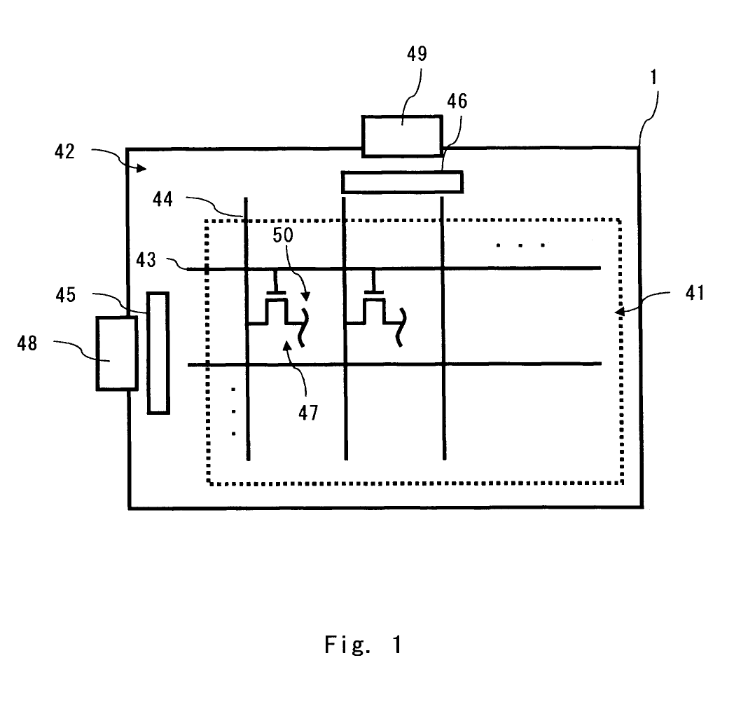

Firstly, a display device to which a TFT array substrate in accordance with the present invention may be applied is explained with reference to FIG. 1. FIG. 1 is a front view showing the structure of a TFT array substrate used for the display device. Although the display device is explained as a liquid crystal display device in the following explanation, it is for illustrative purposes only, and other flat panel display devices or the like including an organic EL (electro luminescence) display device may used for the present invention. The overall structure of this display device is the same from the first through third embodiments described hereinbelow.

A display device in one aspect of the present invention includes a substrate 1. The substrate 1 is for example an array substrate such as a TFT array substrate. The substrate 1 includes a display area 41 and a frame area 42 surrounding the display area 41. A plurality of gate lines (scanning signal lines) 43 and a plurality of source lines (display signal lines) 44 are formed in this display area 41. These plural gate lines 43 are arranged in parallel. Similarly, these plural source lines 44 are also arranged in parallel. The gate lines 43 and source lines 44 cross each other. The gate lines 43 and source lines 44 cross at right angles. The area defined by neighboring gate lines 43 and source lines 44 is a pixel 47. Consequently, the pixels 47 are arranged in matrix on the substrate 1.

In the frame area 42 of the substrate 1, a scanning signal driving circuit 45 and a display signal driving circuit 46 are placed. The gate line 43 extends from the display area 41 to the frame area 42, and connected to the scanning signal driving circuit 45 at the end portion of the substrate 1. Similarly, the source line 44 extends from the display area 41 to the frame area 42, and connected to the display signal driving circuit 46 at the end portion of the substrate 1. An external wiring 48 is connected to the frame area near the scanning signal driving circuit 45. Furthermore, external wiring 49 is connected to the frame area near the display signal driving circuit 46. The external wirings 48 and 49 are for example wiring substrates such as a FPC (Flexible Printed Circuit).

Various external signals are supplied to the scanning signal driving circuit 45 and the display signal driving circuit 46 through the external wirings 48 and 49. The scanning signal driving circuit 45 supplies a gate signal (scanning signal) to the gate line 43 based on an external control signal. The gate lines 43 are selected sequentially by this gate signal. The display signal driving circuit 46 supplies a display signal to the source line 44 based on an external control signal, display data, or the like. In this manner, display voltage corresponding to the display data can be supplied to each pixel 47.

At least one TFT 50 is formed in the pixel 47. The TFT 50 is located near the intersection of the source line 44 and the gate line 43. For example, this TFT 50 supplies a display voltage to a pixel electrode. That is, the TFT 50 which is a switching element is turned on by a gate signal from the gate line 43. In this manner, the display voltage is applied from the source line 44 to the pixel electrode connected to a drain electrode of the TFT 50. An electric field corresponding to the display voltage is produced between the pixel electrode and an opposed electrode. Incidentally, an alignment layer (not shown) is formed on the surface of the substrate 1.

Furthermore, an opposed substrate is arranged opposite to the substrate 1. The opposed substrate is for example a color filter substrate, and located at the viewing side of the substrate 1. A color filter, a black matrix (BM), an opposed electrode, an alignment layer, and the like are formed on the opposed substrate. Incidentally, the opposed electrode may be located on the substrate 1 rather than on the opposed substrate. A liquid crystal layer is sandwiched between the substrate 1 and the opposed substrate. That is, liquid crystal is filled between the substrate 1 and the opposed substrate. Furthermore, a polarizing plate, a retardation film, and the like are provided on the outer surfaces of the substrate 1 and the opposed substrate. Furthermore, a backlight unit or the like is provided on the non-viewing side of the liquid crystal display panel.

The liquid crystal is driven by the electric field between the pixel electrode and the opposed electrode. That is, it changes the orientation direction of the liquid crystal located between the substrates. With this change, the polarization state of light passing through the liquid crystal layer changes. That is, light which passes through the polarization plate becomes linearly polarized light, and it further changes its polarization state by passing through the liquid crystal layer. Specifically, light from the backlight unit becomes linearly polarized light by the polarizing plate located on the array substrate side. As the linearly polarized light passes through the liquid crystal layer, its polarization state changes.

The amount of the light which passes through the polarizing plate located on the opposed substrate side varies depending on the polarization state. That is, the amount of the light which passes through the polarizing plate at the viewing side, out of the transmitted light which is transmitted from the backlight unit to the liquid crystal display panel, varies. The orientation direction of the liquid crystal varies depending on the applied display voltage. Therefore, the amount of the light which passes through the polarizing plate on the viewing side can be changed by controlling the display voltage. That is, a desired image can be displayed by varying the display voltages on a pixel-by-pixel basis.

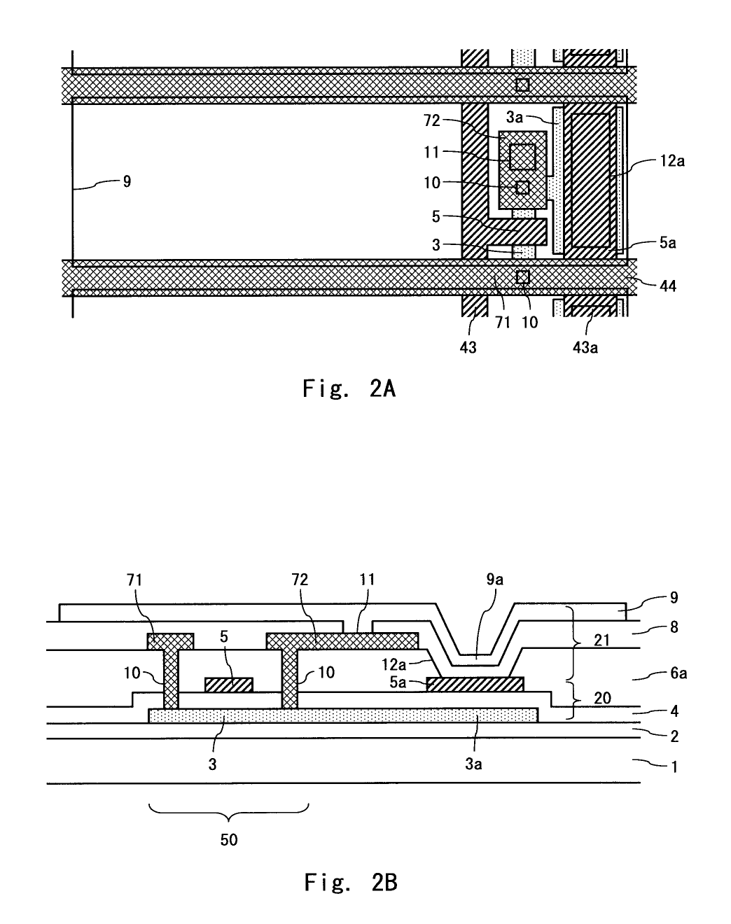

Furthermore, a storage capacitor element (not shown) is also formed in the pixel 47. The structure of a storage capacitor element in accordance with an embodiment of the present invention is explained hereinafter with reference to FIGS. 2A and 2B. FIG. 2A is a plan view showing the structure of a storage capacitor element in accordance with a first embodiment of the present invention. FIG. 2A shows the pixel structure of a top-gate type TFT array substrate in accordance with the first embodiment of the present invention. Furthermore, FIG. 2B is a cross-section view showing the structure of the storage capacitor element in accordance with the first embodiment of the present invention. FIG. 2B shows schematic cross-sectional structure of the TFT and the storage capacitor element shown in FIG. 2A. The TFT 50 is shown in the left side, and the storage capacitor element is shown in the right side of FIG. 2B. Firstly, an undercoat insulating film 2 is formed on a substrate 1 composed of a transparent insulating substrate such as glass in FIGS. 2A and 2B. The undercoat insulating film 2 is composed of, for example, a SiN film of 200 nm in thickness, and prevents impurity diffusion into any element formed above the substrate 1.

An island-shaped semiconductor layer 3 is provided on the undercoat insulating film 2. The semiconductor layer 3 is formed, for example, from polysilicon (poly-crystalline silicon) film of 50 nm in thickness, and includes source/drain regions and a channel region. An impurity is introduced to the source/drain regions. The channel region to which the impurity is not introduced is located between the source region and the drain region. Furthermore, a lower capacitor electrode 3a is formed with and extends from the semiconductor layer 3.

A gate insulating film 4 covers the semiconductor layer 3 and the lower capacitor electrode 3a. The gate insulating film 4 is formed, for example, from a SiO₂ film of 100 nm in thickness. Then, a gate electrode 5 is arranged in the opposed position to the channel region with the gate insulating film 4 interposed therebetween. The gate electrode 5 extends from a gate line 43 formed on the gate insulating film 4. The gate electrode 5 is formed from a Cr film, an Al film, or the like, and has, for example, a thickness of 200 nm. Furthermore, a common line electrode 5a is arranged in the opposed position to the lower capacitor electrode 3a with the gate insulating film 4 interposed therebetween. An area located directly above the lower capacitor electrode 3a in the common line 43a becomes the common line electrode 5a. The common line 43a and gate line 43 are arranged in parallel. That is, the common line electrode 5a is formed between neighboring gate lines 43. The common line electrode 5a is formed from the same metal layer (same layer) as the gate electrode 5. A storage capacitor element 20 is composed of the lower capacitor electrode 3a and the common line electrode 5a which are arranged in opposed positions with the gate insulating film 4 interposed therebetween. When a display voltage is applied from the source line 44 to the lower capacitor electrode 3a, electrical charge corresponding to the display voltage is accumulated in the common line electrode 5a.

An interlayer insulating film 6a covers the gate electrode 5 and the common line electrode 5a. The interlayer insulating film 6a is formed, for example, from a SiO₂ film of 500 nm in thickness. Contact holes 10 piercing the interlayer insulating film 6a and the gate insulating film 4 are formed on the source/drain regions of the semiconductor layer 3. Furthermore, in this embodiment, an area of the interlayer insulating film 6a located above the common line electrode 5 is partially removed to form an opening 12a. The opening 12a is smaller in size than the common line electrode 5a, and located directly above the common line electrode 5a. That is, the opening 12a is formed such that the sides of the common line electrode 5a are covered by the interlayer insulating film 6a. Incidentally, the end portions of the interlayer insulating film 6a which define the sides of the opening 12a have a taper angle.

Wiring electrodes 71 and 72 which constitute a circuit are electrically connected to the source/drain regions of the semiconductor layer 3 through the contact holes 10. The wiring electrodes 71 and 72 are formed, for example, from a Mo film of 300 nm in thickness. The wiring electrode 71 is a source electrode, and the wiring electrode 72 is a drain electrode. The wiring electrode 71 is electrically connected to the source line 44. The wiring electrode 72 is patterned in an island shape, and located between the gate line 43 and the common line 43a. The wiring electrodes 71 and 72 are provided on the interlayer insulating film 6a, but not formed above the opening 12a.

Furthermore, a protective film 8 covers the wiring electrodes 71 and 72 and the interlayer insulating film 6a having the opening 12a. The protective film 8 is formed directly on the common line electrode 5a in the opening 12a, and covers the end portions of the interlayer insulating film 6a which define the sides of the opening 12a, and the area of the common line electrode 5a which defines the bottom of the opening 12a. The protective film 8 is formed, for example, from a SiN film of 200 nm in thickness. Although the thickness of the interlayer insulating film 6a needs to be in the order of 500 nm to reduce the parasitic capacitance between the gate electrode 5 and wiring electrodes 71 and 72, there is no need to consider parasitic capacitance for the protective film 8. Therefore, the thickness of the protective film 8 can be reduced to the order of 100 to 300 nm, the minimum thickness capable of securing the insulation between the wiring electrodes 71 and 72 and the pixel electrode 9 (the detail of which is explained later).

The pixel electrode 9 is formed on the protective film 8, and connected to the wiring electrode 72 through a through hole 11. The pixel electrode 9 is formed, for example, from an ITO film of 100 nm in thickness, and formed generally throughout the pixel 47. In this embodiment, an upper capacitor electrode 9a extends from the pixel electrode 9 such that the upper capacitor electrode 9a is located above the area in which the common line electrode 5a is formed. Therefore, the common line electrode 5a and the upper capacitor electrode 9a, which are opposed each other with at least the protective film 8 interposed therebetween, constitute a storage capacitor element 21.

That is, two storage capacitor elements 20 and 21 are stacked one another by arranging the lower capacitor electrode 3a and the upper capacitor electrode 9a which act as the opposed electrodes above and below the common line electrode 5a respectively. The common line electrode 5a is also used for voltage clamp. Since the upper capacitor electrode 9a is electrically connected to the lower capacitor electrode 3a through the wiring electrode 72 and the semiconductor layer 3, the storage capacitor element 21 and the storage capacitor element 20 are connected in parallel. When a display voltage is applied from the source line 44 to the upper capacitor electrode 9a, electrical charge corresponding to the display voltage is accumulated in the common line electrode 5a.

The upper capacitor electrode 9a and the common line electrode 5a which constitute the storage capacitor element 21 are arranged in the opposed positions only with the protective film 8 interposed therebetween in the opening 12a. That is, the dielectric film of the storage capacitor element 21 is the protective film 8 in the opening 12a, the thickness of which is thinner than the interlayer insulating film 6a. With this structure, the storage capacitance of the storage capacitor element 21 increases significantly since the thickness of the protective film 8 which acts as a dielectric film in the opening 12a is much thinner compared to the interlayer insulating film 6 of the second related art. For example, if the thickness of the interlayer insulating film 6 is 500 nm and the thickness of the protective film 8 is 200 nm, the storage capacitance of the storage capacitor element 21 is 2.5 times as large as that of the storage capacitor element 25 of the second related art.

Next, a method of manufacturing the TFT array substrate in accordance with the first embodiment is explained hereinafter. Firstly, an insulating film such as a silicon nitride film is formed by CVD (Chemical Vapor Deposition) on a substrate 1 composed of a transparent insulating substrate such as a quartz substrate, a glass substrate, or the like to form an undercoat insulating film 2. An amorphous silicon film in the order of 50 nm in thickness is formed on the undercoat insulating film 2 throughout the entire surface of the substrate 1 using a CVD deposition system or the like. After the formation of the amorphous silicon film, the amorphous silicon film is melted, cooled, and solidified to a polysilicon state using an excimer laser annealing equipment or the like. In this manner, a polysilicon film is obtained.

Island shaped resist patterns are formed in respective areas each for a semiconductor layer 3 and a lower capacitor electrode 3a on the polysilicon film by photolithography. The polysilicon film is patterned to island shape by dry-etching using this resist pattern as a mask. Mixed gas of fluoride gas such as CF₄, CHF₃, or SF₆, and oxygen (O₂) or the like is used for the dry-etching. In this manner, a semiconductor layer 3 and a lower capacitor electrode 3a are formed. After the resist pattern is removed, a gate insulating film 4 is formed to cover the semiconductor layer 3 and the lower capacitor electrode 3a. For example, a silicon dioxide film in the order of 100 nm in thickness is formed as the gate insulating film 4 on the entire surface of the substrate 1 by plasma CVD.

Furthermore, a metallic material for a gate electrode 5 is formed on the entire surface of the gate insulating film 4 by sputtering or a similar method. Incidentally, in this embodiment, a Cr film, an alloy film containing Cr as the main ingredient, or the like, these of which are corrosive resistant to the etching process performed for the wiring electrodes 71 and 72 (the detail of which is explained later), is used as the first metal film for the gate electrode 5. In this case, for example, a Cr film is deposited to the order of 200 nm in thickness. Then, resist patterns are formed in the areas for the gate electrode 5, the gate line 43, the common line 43a, and the common line electrode 5a on the Cr film. The Cr film is etched using this resist patterns as a mask to form the gate electrode 5, the gate line 43, the common line 43a, and the common line electrode 5a.

Then, an impurity is introduced in the semiconductor layer 3 using the gate electrode 5 and the resist patterns formed thereon as a mask. The impurity is for example ions of boron (B), phosphorus (P), arsenic (As), or the like. The method of the introduction may be ion implantation with mass separation, or ion doping without mass separation. In this manner, an impurity is introduced in the semiconductor layer 3, and source/drain regions are formed in a self-aligning manner. The resist patters are removed after the impurity introduction.

An interlayer insulating film 6a is formed to cover the gate electrode 5, the gate insulating film 43, the gate insulating film 43a, and the common line electrode 5a. For example, a silicon dioxide film in the order of 500 nm in thickness is formed as the interlayer insulating film 6a on the entire surface of the substrate 1 by plasma CVD. Furthermore, a resist pattern is formed on the interlayer insulating film 6a, and dry-etching is performed using this resist pattern as a mask. In this manner, contact holes 10 piercing through the interlayer insulating film 6a and the gate insulating film 4 are formed, and parts of the source/drain regions of the semiconductor layer 3 are exposed. At this point, in this embodiment, an opening 12a piercing through the interlayer insulating film 6a on the common line electrode 5a is formed, and a part of the common line electrode 5a is exposed. In this manner, the opening 12a is formed simultaneously with the contact holes 10.

A second metal film used for the wiring electrodes 71 and 72 is formed on the interlayer insulating film 6a throughout the entire surface of the substrate 1 by spattering using a DC magnetron. In this embodiment, a Mo film or an alloy film containing Mo as the main ingredient is used as the second metal film for the wiring electrodes 71 and 72. Then, a resist pattern is formed on the second metal film by photolithography, and etching is performed using this resist pattern as a mask.

In this case, mixed gas of SF₆ and O₂ or mixed gas of Cl₂ and O₂ is used for the dry-etching. The etching speed of a Cr film or an alloy film containing Cr as the main ingredient which is used for the common line electrode 5a is substantially zero for these mixed gases. Therefore, although the second metal film formed within the opening 12a is removed by the etching, the common line electrode 5a located under the removed second metal film is not etched during the formation of the wiring electrodes 71 and 72. In this manner, the common line electrode 5a is exposed in the opening 12a, and the wiring electrodes 71 and 72 which are connected to the semiconductor layer 3 through the contact holes 10 are formed. Furthermore, a source line 44 is also formed at the same time. As another combination in which similar effect can be obtained, an Al film or an alloy film containing Al as the main ingredient may be used for the gate electrode 5 and the common line electrode 5a, Mo film or an alloy film containing Mo as the main ingredient may be used for the wiring electrodes 71 and 72, and mixed gas of SF₆ and O₂ may be used for the dry-etching to form the wiring electrodes 71 and 72.

Next, a protective film 8 is formed on the entire surface of the substrate 1 to cover the wiring electrodes 71 and 72 and the source line 44. A silicon nitride film of 200 nm in thickness which is thinner than the interlayer insulating film 6a may be used for the protective film 8. In this manner, the common line electrode 5a in the opening 12a and the end portions of the interlayer insulating film 6a which define the sides of the opening 12a are covered by the protective film 8. Then, when a through hole 11 is formed by dry-etching the protective film 8, a part of the surface of the wiring electrode 72 which is connected to the source/drain regions of the semiconductor layer 3 is exposed.

Next, a pixel electrode 9 is formed on the protective film 8. A transparent conductive film is formed throughout the entire surface of the substrate 1 as the pixel electrode 9, for example, by spattering using a DC magnetron. In general, an ITO film or an IZO film containing indium oxide as the main ingredient is used as the transparent conductive film. Then, the pixel electrode 9 which is connected to the wiring electrode 72 through the through hole 11, and the upper capacitor electrode 9a which extends from the pixel electrode 9 and is arranged in the opposed position to the common line electrode 5a with the protective film 8 interposed therebetween is formed through photolithography, etching, and resist-removal processes. The TFT array substrate in accordance with this embodiment is manufactured through the abovementioned processes.

As explained above, in this embodiment, in addition to the storage capacitor element 20 composed of the lower capacitor electrode 3a and the common line electrode 5a arranged in the opposed positions, the storage capacitor element 21 composed of the common line electrode 5a and the upper capacitor electrode 9a arranged in the opposed positions is stacked on the storage capacitor element 20. At this point, the opening 12a is provided above the common line electrode 5a in the interlayer insulating film 6a, and the upper capacitor electrode 9a and the common line electrode 5a are arranged in the opposed positions only with the protective film 8 interposed therebetween. With this structure, the storage capacitance of the storage capacitor element 21 increases significantly since the thickness of the protective film 8 which acts as a dielectric film in the opening 12a is much thinner compared to the interlayer insulating film 6 of the second related art. Therefore, storage capacitance per unit area increases significantly, and thereby the area occupied by a storage capacitor element can be effectively reduced. That is, it can improve the pixel aperture ratio. Furthermore, since the opening 12a is formed simultaneously with the contact holes 10, the number of processes and the number of necessary masks are not increased.

### Second Embodiment

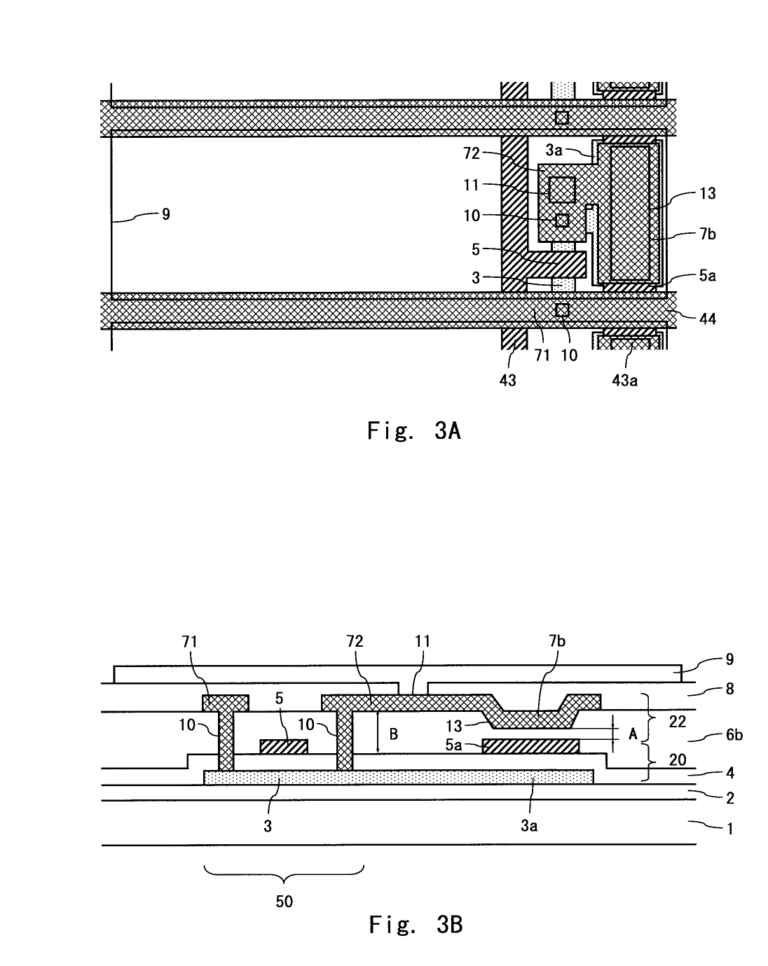

The structure of a storage capacitor element in accordance with a second embodiment of the present invention is explained hereinafter with reference to FIGS. 3A and 3B. FIG. 3A is a plan view showing the structure of the storage capacitor element in accordance with the second embodiment of the present invention. FIG. 3A shows the pixel structure of a top-gate type TFT array substrate in accordance with the second embodiment of the present invention. Furthermore, FIG. 3B is a cross-section view showing the structure of the storage capacitor element in accordance with the second embodiment of the present invention. FIG. 3B shows schematic cross-sectional structure of the TFT and the storage capacitor element shown in FIG. 3A. The TFT 50 is shown in the left side, and the storage capacitor element is shown in the right side of FIG. 3B. In this embodiment, a distinctive feature exists in the structure of the storage capacitor element, and other structures are the same as the first embodiment, and therefore the explanation for those structures are omitted.

In FIGS. 3A and 3B, the same signs are assigned to the same components as in FIGS. 2A and 2B, and the explanation of them is omitted. Similarly to the first embodiment, a lower capacitor electrode 3a which is formed with and extending from a semiconductor layer 3, and a common line electrode 5a which is in the same layer as a gate electrode 5 are arranged in the opposed positions with a gate insulating film 4 interposed therebetween to constitute a storage capacitor element 20. The gate electrode 5 and the common line electrode 5a in accordance with the second embodiment are formed, for example, from a Mo film of 200 nm in thickness. When a display voltage is applied from the source line 44 to the lower capacitor electrode 3a, electrical charge corresponding to the display voltage is accumulated in the common line electrode 5a.

In contrast to the first embodiment, an interlayer insulating film 6b having a thin film portion 13 covers the gate electrode 5 and the common line electrode 5a in this embodiment. That is, the thin film portion 13 of the interlayer insulating film 6b which is formed with thinner film thickness than the remaining portion is located above the common line electrode 5a. The thin film portion 13 is formed by removing a part of the single-layer interlayer insulating film 6b in the direction of film thickness. The thickness A of the interlayer insulating film 6b in the thin film portion 13 is thinner than the thickness B of the interlayer insulating film 6b located over the semiconductor layer 3 other than the formation areas of the gate electrode 5 and the common line electrode 5a. The thin film portion 13 has generally the same size as the common line electrode 5a, and is located directly above the common line electrode 5a. Incidentally, the end portions of the interlayer insulating film 6b which define the sides of the thin film portion 13 have a taper angle.

Then, an upper capacitor electrode 7b is formed as an opposed electrode above the common line electrode 5a with the interlayer insulating film 6b therebetween in the same layer as the wiring electrodes 71 and 72. The wiring electrodes 71 and 72 and the upper capacitor electrode 7b are formed, for example, from Mo/Al/Mo stacked film (with film thicknesses of 50 nm/200 nm/50 nm). The upper capacitor electrode 7b extends from the wiring electrode 72 such that the upper capacitor electrode 7b is located directly above the formation area of the common line electrode 5a. Consequently, the common line electrode 5a and the upper capacitor electrode 7b, which are arranged in the opposed positions with the interlayer insulating film 6b interposed therebetween, constitute a storage capacitor element 22.

That is, two storage capacitor elements 20 and 22 are stacked one another by arranging the lower capacitor electrode 3a and the upper capacitor electrode 7b which act as the opposed electrodes above and below the common line electrode 5a respectively. The common line electrode 5a is also used for voltage clamp. Since the upper capacitor electrode 7b is electrically connected to the lower capacitor electrode 3a through the wiring electrode 72 and the semiconductor layer 3, the storage capacitor element 21 and the storage capacitor element 22 are connected in parallel. When a display voltage is applied from the source line 44 to the upper capacitor electrode 7b, electrical charge corresponding to the display voltage is accumulated in the common line electrode 5a.

The upper capacitor electrode 7b and the common line electrode 5a which constitute the storage capacitor element 22 are arranged in the opposed positions with the interlayer insulating film 6b having thinner film thickness in the thin film portion 13. That is, the dielectric film of the storage capacitor element 22 is the interlayer insulating film 6b in the thin film portion 13, and thinner than the thickness of the interlayer insulating film 6b located over the semiconductor layer 3 other than the formation areas of the gate electrode 5 and the common line electrode 5a. With this structure, the storage capacitance of the storage capacitor element 22 increases significantly since the thickness of the interlayer insulating film 6b which acts as a dielectric film in the thin film portion 13 is much thinner compared to the interlayer insulating film 6 of the second related art.

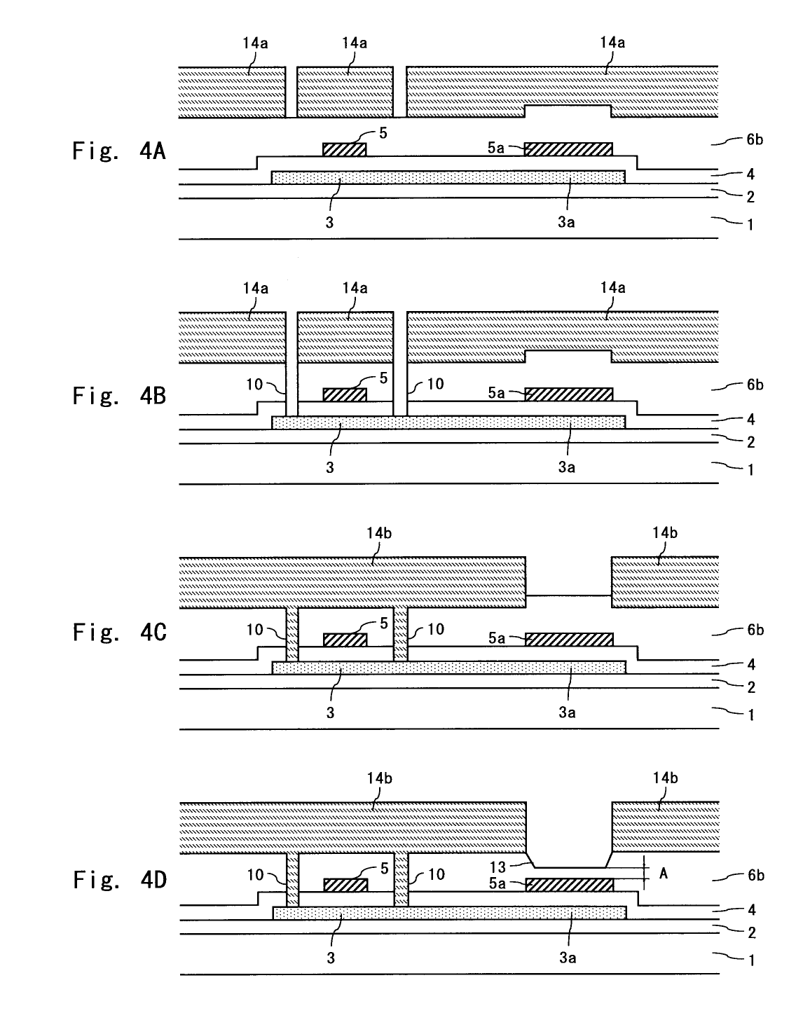

A method of manufacturing a TFT array substrate in accordance with the second embodiment is explained hereinafter with reference to FIGS. 4A to 4D as appropriate. FIGS. 4A to 4D are cross-section views showing an example of the manufacturing process of the TFT array substrate in accordance with the second embodiment. The manufacturing method of the second embodiment is the same as the first embodiment before the formation of the interlayer insulating film 6b, and therefore the explanation of those processes is omitted.

Similarly to the first embodiment, after an interlayer insulating film 6b is formed on the entire surface of the substrate 1 to cover the gate electrode 5 and the common line electrode 5a, a resist pattern 14a is formed by a first photolithography. At this point, as shown in FIG. 4A, the resist pattern 14a is formed on the interlayer insulating film 6b other than the area for contact holes 10. Then, dry-etching is performed using the resist pattern 14a as a mask. In this manner, as shown in FIG. 4B, the contact holes 10 piercing through the interlayer insulating film 6b and the gate insulating film 4 are formed, and parts of the source/drain regions of the semiconductor layer 3 are exposed.

Next, after the resist pattern 14a is removed, a resist pattern 14b is formed by a second photolithography. In this case, as shown in FIG. 4C, the resist pattern 14b is formed on the interlayer insulating film 6b other than the area for a thin film portion 13. Then, dry-etching is performed using the resist pattern 14b as a mask. At this point, the etching is performed partially in the direction of thickness such that the interlayer insulating film 6b is not pierced through, and thereby a part of interlayer insulating film 6b is left to form the thin film portion 13. The etching is continued until the thickness of the thin film portion 13 becomes a desired thickness A as a dielectric film. In this manner, as shown in FIG. 4D, the thickness of the interlayer insulating film 6b in the thin film portion 13 is thinner, and thereby the interlayer insulating film 6b having the contact holes 10 and the thin film portion 13 is formed. Incidentally, the formations of the contact hole 10 and the thin film portion 13 may performed the other way around.

After the resist pattern 14b is removed, a second metal film for the wiring electrodes 71 and 72 is formed on the interlayer insulating film 6b throughout the entire surface of the substrate 1 by spattering using a DC magnetron. A film of Al, Mo, Cr, Ta, or an alloy containing these metals as the main ingredient, or a stacked film of these materials may be used as the second metal film for the wiring electrodes 71 and 72. In this case, a Mo film of 50 nm in thickness, an Al film of 200 nm in thickness, and Mo film of 50 nm in thickness are stacked. Then, this second metal film is patterned through photolithography, etching, and resist-removal processes. In this manner, the wiring electrode 71 which is connected to the semiconductor layer 3 through the contact hole 10 and the upper capacitor electrode 7b which is extending from the wiring electrode 72 to be located above the common line electrode 5a are formed. The thin film portion 13 is covered by the upper capacitor electrode 7b.

Then, a protective film 8 is formed on the entire surface of the substrate 1 to cover the wiring electrodes 71 and 72 and the upper capacitor electrode 7b. A silicon nitride film of 200 nm in thickness may be used for the protective film 8. Then, when a through hole 11 is formed by dry-etching the protective film 8, a part of the surface of the wiring electrode 72 which is connected to the source/drain regions of the semiconductor layer 3 is exposed.

A pixel electrode 9 is formed on the protective film 8. A transparent conductive film is formed throughout the entire surface of the substrate 1 as the pixel electrode 9, for example, by spattering using a DC magnetron. In general, an ITO film or an IZO film containing indium oxide as the main ingredient is used as the transparent conductive film. Then, the pixel electrode 9 which is connected to the wiring electrode 72 through the through hole 11 is formed through photolithography, etching, and resist-removal processes. The TFT array substrate in accordance with this embodiment is manufactured through the abovementioned processes.

Incidentally, in this embodiment, the common line electrode 5a is not exposed in the etching process of the wiring electrodes 71 and 72. Therefore, there is no need for using material which is corrosive resistant to the etching process performed for the wiring electrodes 71 and 72 as the metal film for the gate electrode 5. Consequently, a film of Mo, Cr, W, Al, Ta, or an alloy containing these metals as the main ingredient can be used as the metal film for the gate electrode 5 and the common line electrode 5a.

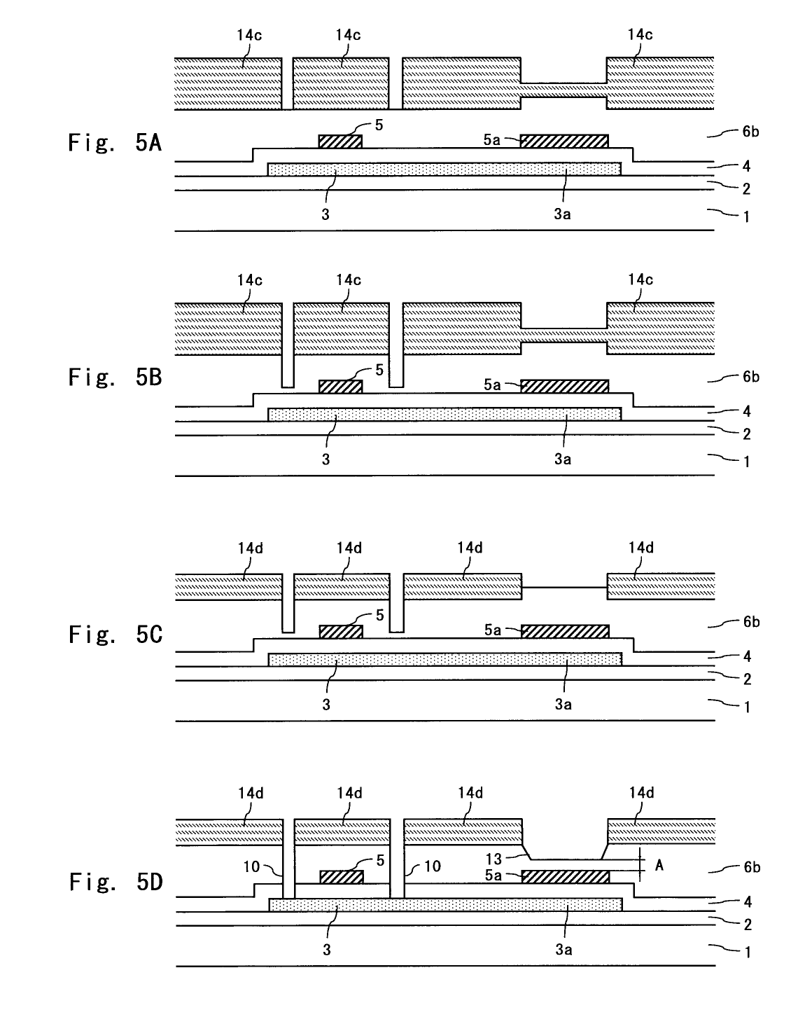

In this embodiment, both of the contact holes 10 and the thin film portion 13 can be formed with a single photolithography process by using a multiple tone exposure technique. FIGS. 5A to 5D are cross-section views showing another example of the manufacturing process of the TFT array substrate in accordance with the second embodiment. After a resist is coated on the interlayer insulating film 6b, the resist is patterned by multiple tone exposure using a halftone mask or a gray-tone mask and development. In this manner, a resist pattern 14c having different film thicknesses as shown in FIG. 5A is formed on the interlayer insulating film 6b except for the areas for the contact holes 10. The thickness of this resist pattern 14c is thinner in the area for the thin film portion 13, and thicker in the remaining area.

Then, a first partial etching is performed using this resist pattern 14c as a mask. At this point, the dry-etching is continued until the thickness of the stacked film composed of the interlayer insulating film 6b and the gate insulating film 4 in the areas for the contact holes 10 becomes a desired thickness. That is, the stacked film is partially removed in the direction of thickness by the etching. In this manner, as shown in FIG. 5B, the thickness of the stacked film in the formation areas of the contact holes 10 is reduced to the desired thickness.

Next, the resist pattern 14c is subjected to ashing. The ashing is continued until the surface of the interlayer insulating film 6b is exposed in the area for the thin film portion 13. In this manner, as shown in FIG. 5C, the resist pattern 14c is removed in the area having a thinner thickness, and reduced in thickness in the areas having thicker thickness and left as a resist pattern 14d. Then, a second partial etching is performed using this resist pattern 14d as a mask. At this point, the etching is performed partially in the direction of thickness such that the interlayer insulating film 6b is not pierced through, and thereby a part of interlayer insulating film 6b is left to form the thin film portion 13. The dry-etching is continued until the thickness of the thin film portion 13 becomes a desired thickness A as a dielectric film. In this manner, as shown in FIG. 5D, while the thickness of the interlayer insulating film 6b becomes thinner in the thin film portion 13, the stacked film is removed in the formation areas of the contact holes 10, and thereby the semiconductor layer 3 is exposed there. That is, the interlayer insulating film 6b having the contact holes 10 and the thin film portion 13 is formed.

As explained above, in this embodiment, in addition to the storage capacitor element 20 composed of the lower capacitor electrode 3a and the common line electrode 5a arranged in the opposed positions, the storage capacitor element 22 composed of the common line electrode 5a and the upper capacitor electrode 7b arranged in the opposed positions is stacked on the storage capacitor elements 20. At this point, the thin film portion 13 is formed above the common line electrode 5a in the interlayer insulating film 6b, and the common line electrode 5a and the upper capacitor electrode 7b are arranged in the opposed positions with the thin film portion 13 interposed therebetween. With this structure, the storage capacitance of the storage capacitor element 22 increases significantly since the thickness A of the interlayer insulating film 6b which acts as a dielectric film in the thin film portion 13 is much thinner compared to the interlayer insulating film 6 of the second related art. Therefore, storage capacitance per unit area increases significantly, and thereby the area occupied by a storage capacitor element can be effectively reduced. That is, it can improve the pixel aperture ratio. Furthermore, since the thin film portion 13 is formed simultaneously with the contact holes 10 by multiple tone exposure, the number of necessary masks is not increased.

### Third Embodiment

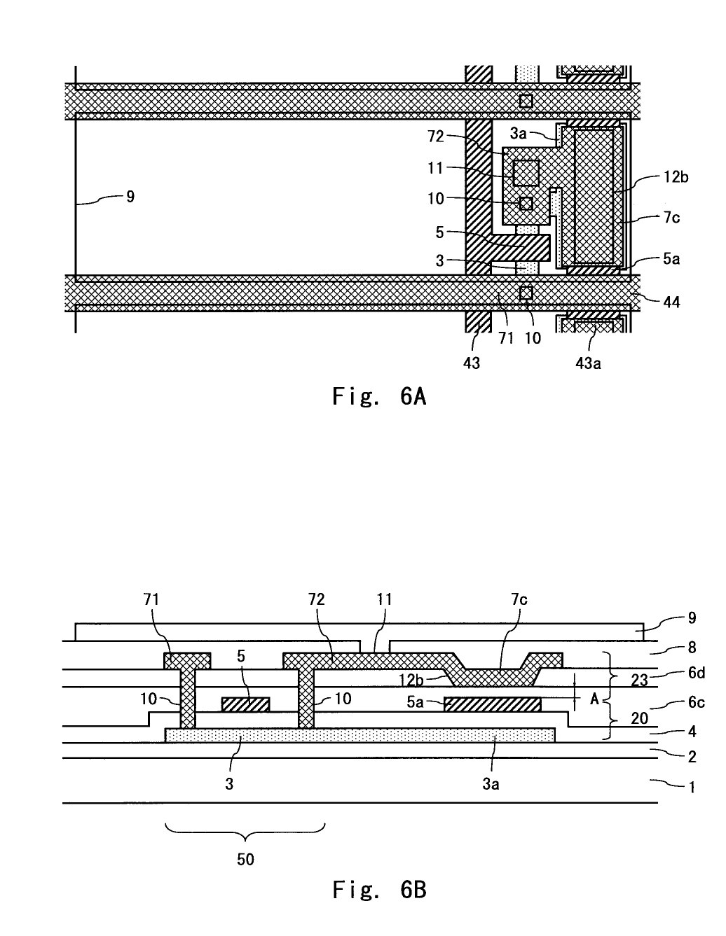

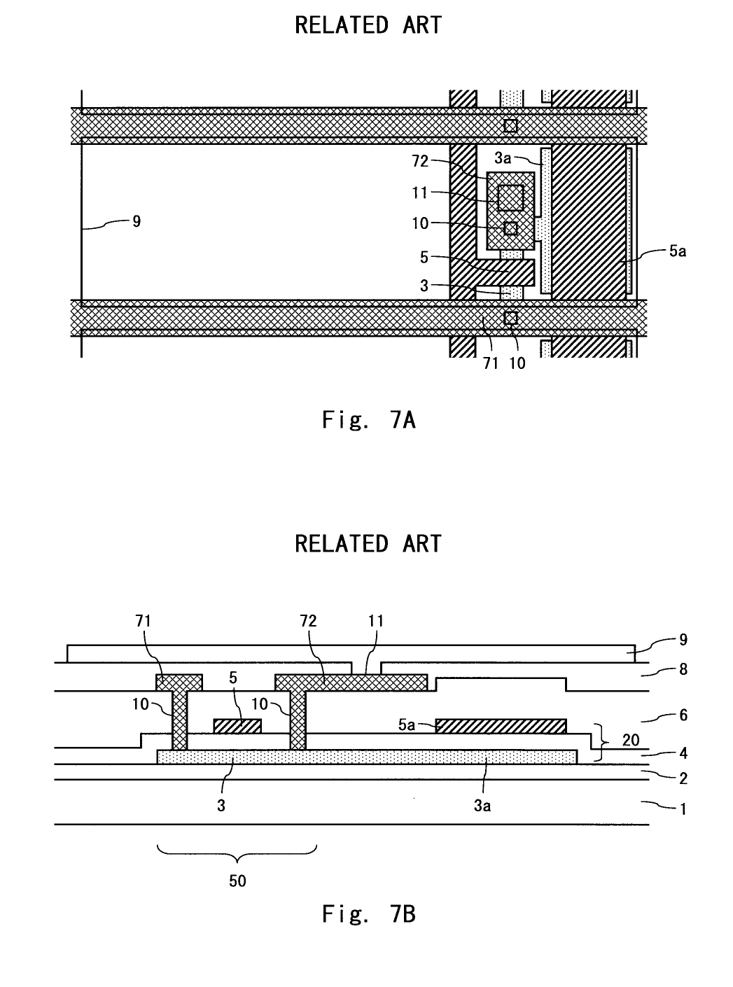

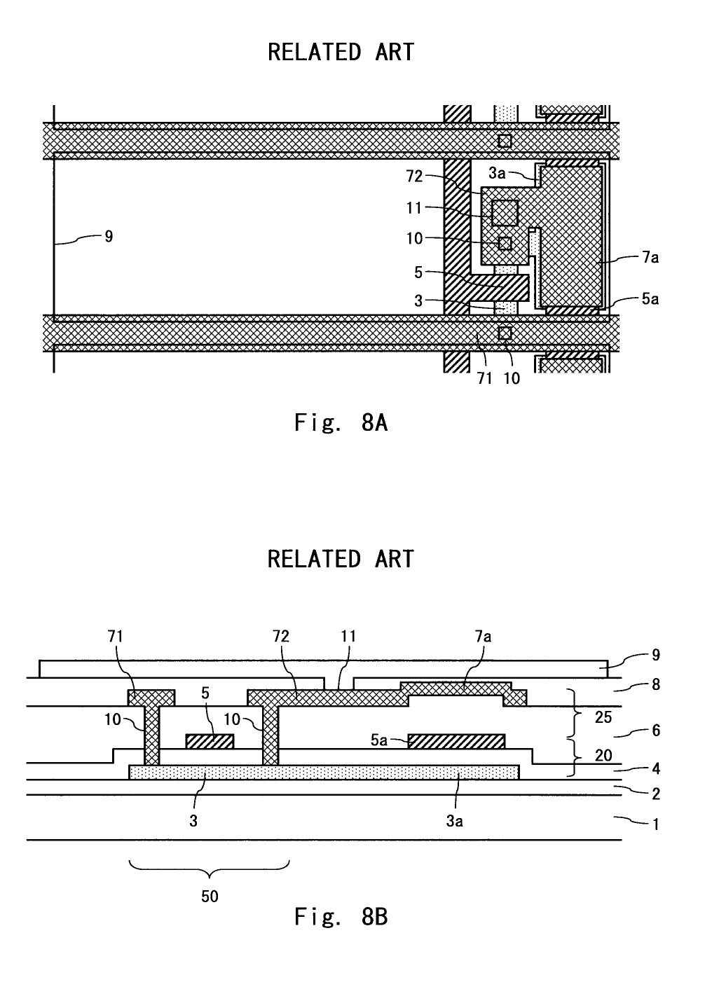

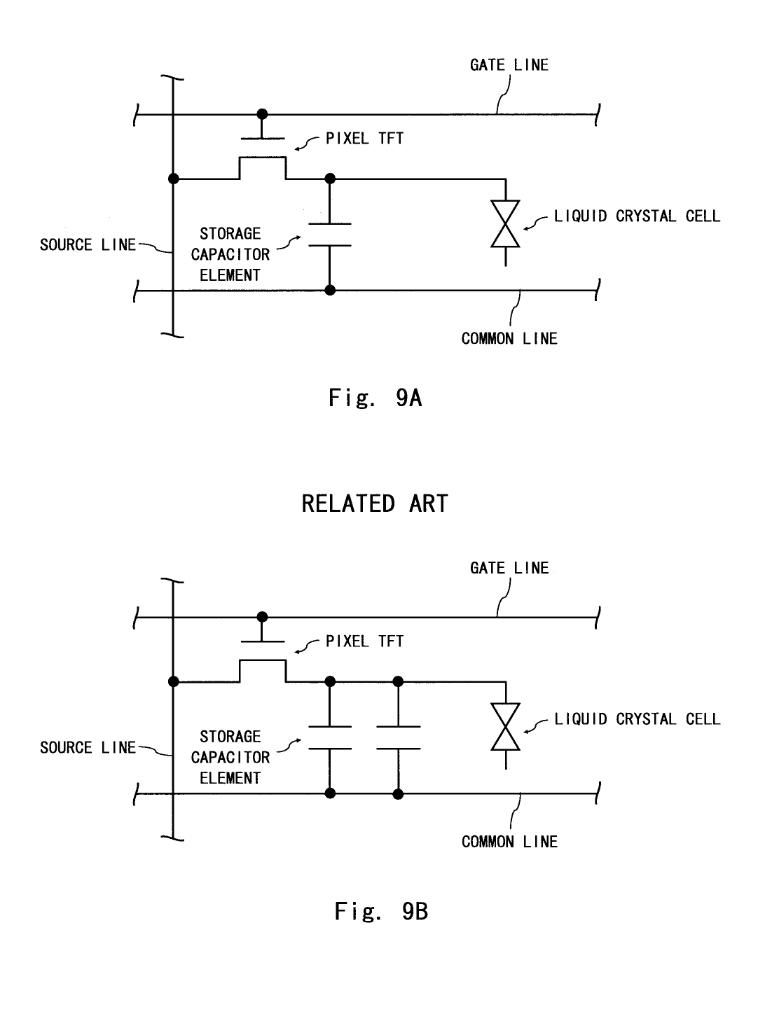

The structure of a storage capacitor element in accordance with a third embodiment of the present invention is explained hereinafter with reference to FIGS. 6A and 6B. FIG. 6A is a plan view showing the structure of the storage capacitor element in accordance with the third embodiment of the present invention. FIG. 6A shows the pixel structure of a top-gate type TFT array substrate in accordance with the third embodiment of the present invention. Furthermore, FIG. 6B is a cross-section view showing the structure of the storage capacitor element in accordance with the third embodiment of the present invention. FIG. 6B shows schematic cross-sectional structure of the TFT and the storage capacitor element shown in FIG. 6A. The TFT 50 is shown in the left side, and the storage capacitor element is shown in the right side of FIG. 6B. This embodiment has a different interlayer insulating film from the second embodiment, and other structures are the same as the second embodiment, and therefore the explanation for those structures are omitted.

In FIGS. 6A and 6B, the same signs are assigned to the same components as in FIGS. 3A and 3B, and the explanation of them is omitted. Similarly to the second embodiment, a lower capacitor electrode 3a which is formed with and extending from a semiconductor layer 3, and a common line electrode 5a which is in the same layer as a gate electrode 5 are arranged in the opposed positions with a gate insulating film 4 interposed therebetween to constitute a storage capacitor element 20. When a display voltage is applied from the source line 44 to the lower capacitor electrode 3a, electrical charge corresponding to the display voltage is accumulated in the common line electrode 5a.

In contrast to the second embodiment, in this embodiment, a first interlayer insulating film 6c is formed to cover the gate electrode 5 and the common line electrode 5a. Furthermore, a second interlayer insulating film 6d having an opening 12b is stacked on the first interlayer insulating film 6c. That is, the second interlayer insulating film 6d is removed in the area above the common line electrode 5a, and the opening 12b is formed. The opening 12b has generally the same size as the common line electrode 5a, and is located directly above the common line electrode 5a. Incidentally, the end portions of the interlayer insulating film 6d which define the sides of the opening 12b have a taper angle. The first interlayer insulating film 6c is thinner than the interlayer insulating film 6b of the second embodiment, and has a desired thickness A as a dielectric film above the common line electrode 5a. The first interlayer insulating film 6c has no opening. Furthermore, contact holes 10 piercing through the first interlayer insulating film 6c, the second interlayer insulating film 6d, and the gate insulating film 4 are formed in the source/drain regions of the semiconductor layer 3.

Wiring electrodes 71 and 72 formed on the second interlayer insulating film 6d are electrically connected to the source/drain regions of the semiconductor layer 3 through the contact holes 10. Furthermore, the wiring electrodes 71 and 72 extend such that the wiring electrodes 71 and 72 cover the end portions of the second interlayer insulating film 6d which define the sides of the opening 12b and the area of the second interlayer insulating film 6c which defines the bottom of the opening 12b, and thereby forming an upper capacitor electrode 7c in the area directly above the common line electrode 5a. Therefore, the common line electrode 5a and the upper capacitor electrode 7c, which are opposed each other with the first interlayer insulating film 6c interposed therebetween, constitute a storage capacitor element 23.

That is, two storage capacitor elements 20 and 23 are stacked one another by arranging the lower capacitor electrode 3a and the upper capacitor electrode 7c which act as the opposed electrodes above and below the common line electrode 5a respectively. The common line electrode 5a is also used for voltage clamp. Since the upper capacitor electrode 7c is electrically connected to the lower capacitor electrode 3a through the wiring electrode 72 and semiconductor layer 3, the storage capacitor element 21 and the storage capacitor element 23 are connected in parallel. When a display voltage is applied from the source line 44 to the upper capacitor electrode 7c, electrical charge corresponding to the display voltage is accumulated in the common line electrode 5a.

The upper capacitor electrode 7c and common line electrode 5a which constitute the storage capacitor element 23 are arranged in the opposed positions only with the first interlayer insulating film 6c interposed therebetween in the opening 12b of the second interlayer insulating film 6d. That is, since the second interlayer insulating film 6d is removed in the opening 12b, a thinner film portion is formed in the stacked film composed of the first interlayer insulating film 6c and the second interlayer insulating film 6d. Therefore, the dielectric film of the storage capacitor element 23 is formed from the thinner film portion of the stacked film, and thinner than the stacked film located over the semiconductor layer 3 other than the formation areas of the common line electrode 5a. With this structure, the storage capacitance of the storage capacitor element 23 increases significantly since the thickness of the first interlayer insulating film 6c which acts as a dielectric film is much thinner compared to the interlayer insulating film 6 of the second related art.

A method of manufacturing the TFT array substrate in accordance with the third embodiment is explained hereinafter. The manufacturing method of the third embodiment is the same as the second embodiment except for the process for the interlayer insulating film formation, and therefore the explanation of other processes is omitted.

After a first interlayer insulating film 6c is formed on the entire surface of the substrate 1 to cover the gate electrode 5 and the common line electrode 5a, a second interlayer insulating film 6d is formed on the entire surface of the substrate 1. For example, a TEOS (Tetra Ethyl Ortho Silicate) film having thickness A is deposited as the first interlayer insulating film 6c using plasma CVD containing TEOS or a similar manner. Furthermore, a silicon nitride film is deposited as the second interlayer insulating film 6d using plasma CVD or a similar manner. The stacked film composed of the first and second interlayer insulating films 6c and 6d is formed such that the thickness of the stacked film becomes in the order of 500 nm, the minimum thickness to reduce the parasitic capacitance between the gate electrode 5 and the wiring electrodes 71 and 72.

Next, similarly to the embodiment, a resist pattern 14a is formed on the second interlayer insulating film 6d except for the areas for contact holes 10 by a first photolithography. Dry-etching is performed using this resist pattern 14a as a mask, and parts of the source/drain regions of the semiconductor layer 3 are exposed. In this manner, the contact holes 10 piercing through the first and second interlayer insulating films 6c and 6d and the gate insulating film 4 are formed.

Similarly to the second embodiment, after the resist pattern 14a is removed, a resist pattern 14b is formed by a second photolithography. That is, the resist pattern 14b is formed on the second interlayer insulating film 6d except for the area for an opening 12b. Then, dry-etching is performed using this resist pattern 14b as a mask. At this point, the second interlayer insulating film 6d is selectively etched. For example, if the dry-etching is performed with mixed gas of CF₄, CO, and Ar, the etching selectivity of silicon nitride film to TEOS film becomes in the order of 1.7, and thereby it allows the selective etching by using the etching rate difference. In this manner, the second interlayer insulating film 6d is removed in the area directly above the common line electrode 5a by the etching, and the opening 12b in which the first interlayer insulating film 6c is exposed is formed.

The same processes as in the second embodiment are used for the subsequent processes. That is, after the resist pattern 14b is removed, a second metal film for the wiring electrodes 71 and 72 is formed on the second interlayer insulating film 6d. This second metal film is patterned through photolithography, etching, and resist-removal processes. In this manner, the wiring electrode 71 which is connected to the semiconductor layer 3 through the contact hole 10 and the upper capacitor electrode 7c which is extending from the wiring electrode 72 to be located above the common line electrode 5a are formed. The opening 12b and the end portions of the second interlayer insulating film 6d which define the sides of the opening 12b are covered by the upper capacitor electrode 7c.

Then, a protective film 8 is formed to cover the wiring electrodes 71 and 72 and the upper capacitor electrode 7c, and then a through hole 11 is formed through photolithography, etching, and resist-removal processes. Furthermore, a pixel electrode 9 which is connected to the wiring electrode 72 through the through hole 11 is formed on the protective film 8. The TFT array substrate in accordance with this embodiment is manufactured through the abovementioned processes.

As explained above, in this embodiment, the stacked film of the first interlayer insulating film 6c and the second interlayer insulating film 6d is formed as an interlayer insulating film. Then, in addition to the storage capacitor element 20 composed of the lower capacitor electrode 3a and the common line electrode 5a arranged in the opposed positions, the storage capacitor element 23 composed of the common line electrode 5a and the upper capacitor electrode 7c arranged in the opposed positions is stacked on the storage capacitor element 20. At this point, the opening 12b is formed above the common line electrode 5a in the second interlayer insulating film 6d, and the common line electrode 5a and the upper capacitor electrode 7c are arranged in the opposed positions with the first interlayer insulating film 6c interposed therebetween. With this structure, the storage capacitance of the storage capacitor element 23 increases significantly since the thickness A of the first interlayer insulating film 6c which acts as a dielectric film is much thinner compared to the interlayer insulating film 6 of the second related art. Therefore, storage capacitance per unit area increases significantly, and thereby the area occupied by a storage capacitor element can be effectively reduced. That is, it can improve the pixel aperture ratio.

Incidentally, although an active matrix type liquid crystal display device is used in the first through third embodiments, the present invention is not limited to those display devices. For example, a display device using display material other than liquid crystal, such as an organic EL display device and an electronic paper may be used for the present invention.

The embodiments in accordance with the present invention are explained above for illustrative purpose only, and the present invention is not limited to those embodiments. Furthermore, the modifications, additions, and transformations of the components of the embodiments are apparent to those skilled in the art without departing from the scope of the present invention.

From the invention thus described, it will be obvious that the embodiments of the invention may be varied in many ways. Such variations are not to be regarded as a departure from the spirit and scope of the invention, and all such modifications as would be obvious to one skilled in the art are intended for inclusion within the scope of the following claims.

What is claimed is:

1. A thin film transistor array substrate comprising:
a semiconductor layer formed over a substrate and having source/drain regions;
a gate insulating film covering the semiconductor layer;
a gate electrode arranged in the opposed position to the channel region of the semiconductor layer with the gate insulating film interposed therebetween;
an interlayer insulating film covering the gate electrode;
a wiring electrode connected to the source/drain regions through a contact hole piercing through the interlayer insulating film and the gate insulating film;
a protective film covering the wiring electrode and the interlayer insulating film;
a pixel electrode connected to the wiring electrode through a through hole piercing through the protective film;
a lower capacitor electrode formed with and extending from the semiconductor layer;
a common line electrode formed from the same layer as the gate electrode and arranged in the opposed position to the lower capacitor electrode with the gate insulating film interposed therebetween; and
an upper capacitor electrode arranged in the opposed position to the common line electrode with a dielectric film having film thickness thinner than the interlayer insulating film interposed therebetween.

2. The thin film transistor array substrate according to claim 1, wherein
an area of the interlayer insulating film located above the common line electrode is removed to form an opening,
the protective film covers the opening and the sides of the interlayer insulating film that form an outline of the opening,
the dielectric film is formed from the protective film in the opening, and
the upper capacitor electrode arranged in the opposed position to the common line electrode with the dielectric film interposed therebetween is formed with and extending from the pixel electrode.

3. The thin film transistor array substrate according to claim 2, wherein
the common line electrode is formed from a Cr film, an alloy film containing Cr as the main ingredient, an Al film, or an alloy film containing Al as the main ingredient, and
the wiring electrode is formed from a Mo film, an alloy film containing Mo as the main ingredient.

4. The thin film transistor array substrate according to claim 1, wherein
a thin film portion having film thickness thinner than the interlayer insulating film located in an area distant from the common line electrode over the semiconductor layer is formed in an area of the interlayer insulating film located above the common line electrode,
the dielectric film is formed from the thin film portion of the interlayer insulating film, and
the upper capacitor electrode arranged in the opposed position to the common line electrode with the dielectric film interposed therebetween is formed with and extending from the wiring electrode to cover the thin film portion and the sides of the interlayer insulating film that form an outline of the thin film portion.

5. The thin film transistor array substrate according to claim 4, wherein
the interlayer insulating film comprises a first interlayer insulating film covering the gate electrode and the common line electrode, and a second interlayer insulating film formed on the first interlayer insulating film, and
the thin film portion is formed by removing the second interlayer insulating film in the area above the common line electrode.

6. The thin film transistor array substrate according to claim 4, wherein
the interlayer insulating film is formed from a single-layer interlayer insulating film covering the gate electrode and the common line electrode, and
the thin film portion is formed by removing the single-layer interlayer insulating film partially in the direction of thickness.

7. A display device comprising the thin film transistor array substrate of claim 1.

8. A method of manufacturing a thin film transistor array substrate, comprising:
a step for forming a semiconductor layer having source/drain regions, and a lower capacitor electrode extending from the semiconductor layer over a substrate;
a step for forming a gate insulating film covering the semiconductor layer and the lower capacitor electrode;
a step for forming a gate electrode arranged in the opposed position to the channel region of the semiconductor layer with the gate insulating film interposed therebetween, and a common line electrode arranged in the opposed position to the lower capacitor electrode with the gate insulating film interposed therebetween;
a step for forming an interlayer insulating film covering the gate electrode and the common line electrode;
a step for forming a contact hole with the source/drain regions being exposed and an opening with the common line electrode being exposed by etching the interlayer insulating film and the gate insulating film;
a step for forming a wiring electrode connected to the source/drain regions through the contact hole;
a step for forming a protective film having film thickness thinner than the interlayer insulating film so as to cover the wiring electrode, the interlayer insulating film, and the opening, and to have a through hole with a part of the wiring electrode being exposed; and
a step for forming a pixel electrode connected to the wiring electrode through the through hole and arranged in the opposed position to the common line electrode with the protective film interposed therebetween.

9. The method of manufacturing a thin film transistor array substrate according to claim 8, wherein
in the step for forming the gate electrode and the common line electrode, the gate electrode and the common line electrode are formed from a Cr film, an alloy film containing Cr as the main ingredient, an Al film, or an alloy film containing Al as the main ingredient, and
in the step for forming the wiring electrode, the wiring electrode is formed from a Mo film, an alloy film containing Mo as the main ingredient.

10. The method of manufacturing a thin film transistor array substrate according to claim 9, wherein
in the step for forming the wiring electrode, the wiring electrode is formed by dry-etching using mixed gas of SF₆ and O₂, or mixed gas of Cl₂ and O₂.

11. A method of manufacturing a thin film transistor array substrate, comprising:
a step for forming a semiconductor layer having source/drain regions, and a lower capacitor electrode extending from the semiconductor layer over a substrate;
a step for forming a gate insulating film covering the semiconductor layer and the lower capacitor electrode;
a step for forming a gate electrode arranged in the opposed position to the channel region of the semiconductor layer with the gate insulating interposed therebetween, and a common line electrode arranged in the opposed position to the lower capacitor electrode with the gate insulating film interposed therebetween;
a step for forming an interlayer insulating film covering the gate electrode and the common line electrode;
a step for forming a contact hole with the source/drain regions being exposed and a thin film portion having thinner film thickness in the interlayer insulating film above the common line electrode by etching the interlayer insulating film and the gate insulating film;
a step for forming a wiring electrode connected to the source/drain regions through the contact hole and arranged in the opposed position to the common line electrode with the thin film portion in the interlayer insulating film interposed therebetween;
a step for forming a protective film so as to cover the wiring electrode and the interlayer insulating film and to have a through hole with a part of the wiring electrode being exposed; and
a step for forming a pixel electrode connected to the wiring electrode through the through hole.

12. The method of manufacturing a thin film transistor array substrate according to claim 11, wherein the step for forming the contact hole and the thin film portion includes:
a step for etching the interlayer insulating film and the gate insulating film using a first resist pattern formed on the interlayer insulating film as a mask to form the contact hole; and
a step for etching the interlayer insulating film partially in the direction of thickness using a second resist pattern formed on the interlayer insulating film as a mask to form the thin film portion.

13. The method of manufacturing a thin film transistor array substrate according to claim 11, wherein the step for forming the contact hole and the thin film portion includes:
a step for forming a resist pattern having film thickness difference on the interlayer insulating film by multiple tone exposure;
a step for etching and removing a stacked film of the interlayer insulating film and the gate insulating film partially in the direction of thickness in the area for the contact hole using the resist pattern having the film thickness difference as a mask;
a step for ashing the resist pattern having the film thickness difference to remove the thin film part of the resist pattern; and
a step for etching the stacked film in the area for the contact hole using the resist pattern with the thin film part being removed as a mask to form the contact hole, and etching the interlayer insulating film partially in the direction of thickness in the area for the thin film portion to form the thin film portion.

14. The method of manufacturing a thin film transistor array substrate according to claim 11, wherein
in the step for forming the interlayer insulating film, a first interlayer insulating film covering the gate electrode and the common line electrode is formed, and then a second interlayer insulating film is formed on the first interlayer insulating film, and
in the step for forming the contact hole and the thin film portion, the thin film portion is formed by removing the second interlayer insulating film in the area above the common line electrode to expose the first interlayer insulating film.

15. The method of manufacturing a thin film transistor array substrate according to claim 14, wherein
in the step for forming the interlayer insulating film, a first interlayer insulating film is formed by a CVD using TEOS, and then a second interlayer insulating film is formed from a silicon nitride film, and
the step for forming the contact hole and the thin film portion includes:
a step for etching the interlayer insulating film and the gate insulating film using a first resist pattern formed on the interlayer insulating film as a mask to form the contact hole; and
a step for dry-etching the second interlayer insulating film with mixed gas of CF₄, CO, and Ar using a second resist pattern formed on the interlayer insulating film as a mask to form the thin film portion.
